(19) United States
(12) Patent Application Publication
(10) Pub. No.: US 2005/0035453 A1
(43) Pub. Date: Feb. 17, 2005

(54) Bump transfer fixture

(76) Inventors: Kwun-Yao Ho, Hsin-Tien City (TW); Moriss Kung, Hsin-Tien City (TW)

Correspondence Address: J C PATENTS, INC., 4 VENTURE, SUITE 250, IRVINE, CA, 92618, US

(21) Appl. No.: 10/739,638

(22) Filed: Dec. 17, 2003

(30) Foreign Application Priority Data
Aug. 14, 2003 (TW) 92214706

(51) Int. Cl. H01L 23/48

(52) U.S. Cl. 257/739

(57) ABSTRACT

A bump transfer fixture for accommodating a plurality of bumps is provided. The bump transfer fixture includes a transfer plate having a plurality of fix structures. The plurality of fix structures are disposed on the surface of the transfer plate. Each of the plurality of fix structures accommodates one of the bumps. The fix structures can be concave or convex structures. By using the transfer plate to form the bumps, no photolithography technology is used to form the patterned photoresist layer. Hence, the bump transfer process is much simpler and faster. Therefore, the present invention effectively reduces the cost and time for the bump transfer process.

### CROSS-REFERENCE TO RELATED APPLICATION

This application claims the priority benefit of Taiwan application serial no. 92214706, filed on Aug. 14, 2003, the full disclosure of which is incorporated herein by reference.

### BACKGROUND OF THE INVENTION

1. Field of the Invention

This invention generally relates to a flip-chip bump process, and more particularly to a bump transfer fixture for a bump transfer process.

2. Description of Related Art

Flip chip interconnect technology is widely used for chip packaging. Flip Chip describes the method of electrically and mechanically connecting a die to a package carrier. The package carrier then provides the connection from the die to the exterior of the package. The interconnection between die and carrier in flip chip packaging is made through a plurality of conductive bumps that are placed directly on the die surface. The bumped die is then flipped over and placed face down, with the bumps electrically and mechanically connecting to the carrier. After the die is soldered, underfill is applied between the die and the carrier around the bumps. The underfill is designed to contract the stress in the solder joints caused by the difference in thermal expansion between the silicon die and carrier.

The boom in flip chip packaging results both from flip chip's advantages in size, performance, flexibility, reliability, and cost over other packaging methods and from the widening availability of flip chip materials, equipment, and services. Flip chip connections can use the whole area of the die, accommodating more connections on a smaller die. Hence, Flip chip technology is suitable for high pin count package. Some of well known applications of flip chip technology are flip chip ball grid array (“FC/BGA”) and flip chip pin grid array (“FC/PGA”)

FIGS. 1A-1F show the bump transfer processes. Referring to FIG. 1A, a substrate 100 is provided as a support structure for forming solder bumps 120 (see FIG. 1C). The substrate 100 is glass or plastic substrate, which has a plane surface. Referring to FIG. 1B, a patterned photoresist layer 110 is formed on the surface 102 of the substrate 100. The patterned photoresist layer 110 has a plurality of openings 112. Referring to FIG. 1C, a plurality of solder bumps 120 are formed in the openings 120. Those solder bumps 120 then become independent ball-shape bumps in the openings 112 after reflow. The solder bumps 120 can be formed by printing or electrolytic plating.

Referring to FIG. 1D, the photoresist layer 110 and the remaining solder 114 on the photoresist layer 110 are removed. Hence, only the solder bumps 120 are left on the substrate 100. Referring to FIG. 1E, a wafer 130 is placed at the top of the substrate 100, and the solder bumps 120 corresponds to the bump pads 132 on the wafer 130. After reflowing the solder bumps 120, the solder bumps 120 are transferred to the bump pads 132. Referring to FIG. 1F, the substrate 100 is removed during the reflow process. Because the bump pads 132 have a better adhesion than the substrate 100, the solder bumps 120 are transferred to the bump pads 132. Hence, the solder bumps 120 on the bump pads 132 are used for electrically and mechanically connecting to the carrier (not shown).

It should be noted that the above bump transfer process has at least the following disadvantages:

1. If the solder bumps are formed by printing, voids are commonly formed within the solder bumps, which will seriously affect the reliability of the chip package structure.

2. If the solder bumps are formed by printing or electrolytic plating, the photolithography processes will be involved to form the patterned photoresist layer, which are expensive processes and are difficult to control.

3. After forming the patterned photoresist layer, several wet cleaning steps are required to remove the solvents remaining on the surface of the wafer, and to remove the patterned photoresist layer after the formation of the solder bumps. Hence, the process time becomes much longer. Further, the solvents for printing or electrolytic plating will contaminate the environment.

### SUMMARY OF THE INVENTION

An object of the present invention is to provide a bump transfer fixture to simplify the bump transfer process and reduce the cost of the process.

The present invention provides a bump transfer fixture for accommodating a plurality of bumps. The bump transfer fixture at least comprises a transfer plate having a plurality of fix structures, wherein the plurality of fix structures being disposed on the surface of the transfer plate, each of the plurality of fix structures accommodating one of the bumps. The fix structures can be concave or convex structures.

The present invention provides a bump transfer fixture to effectively transfer the solder bumps to the wafer without photolithography process. Hence the present invention simplifies the process for forming bumps and does not require wet cleaning steps, which saves time and cost of the bump transfer process.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIGS. 1A-1F show the conventional bump transfer process.

FIGS. 2A-2D show the bump transfer process in accordance with the first embodiment of the present invention.

FIGS. 3A-3D show the bump transfer process in accordance with the second embodiment of the present invention.

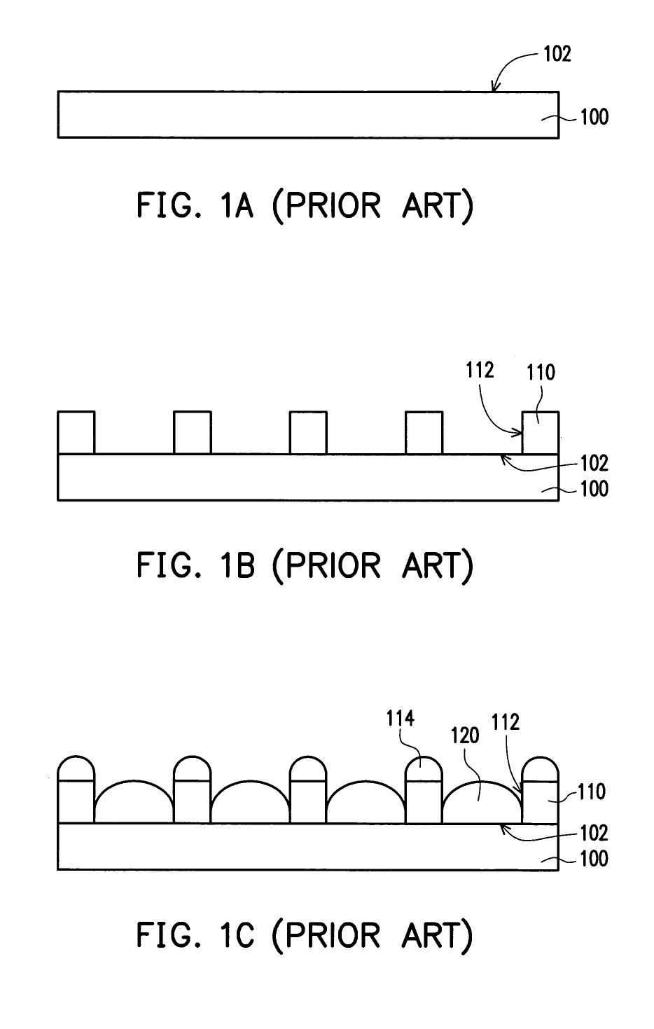

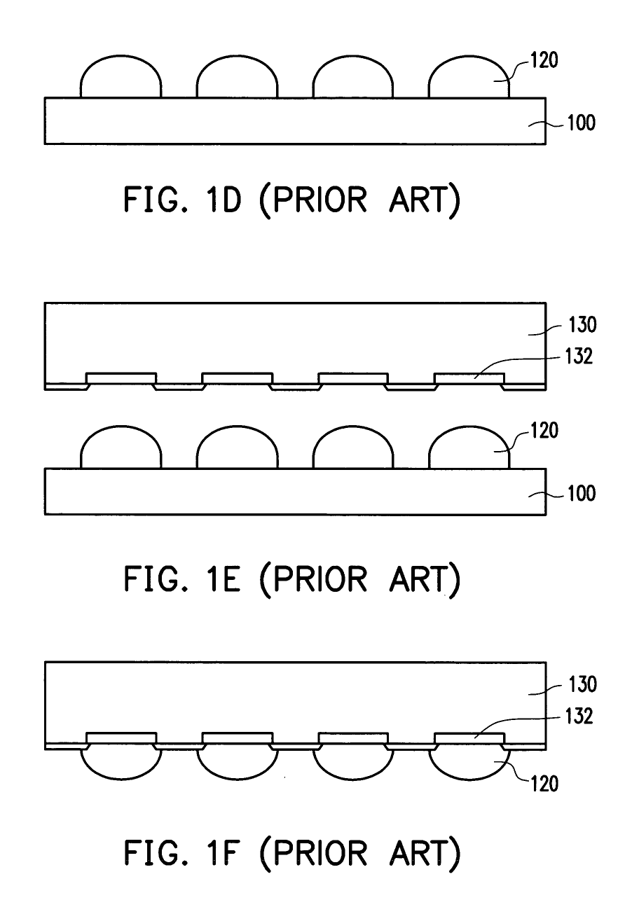

### DESCRIPTION OF THE PREFERRED EMBODIMENTS

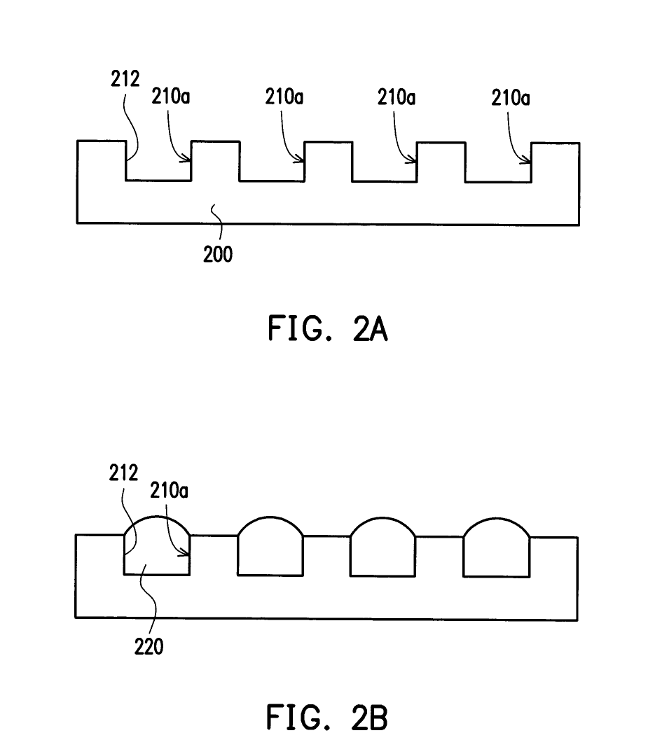

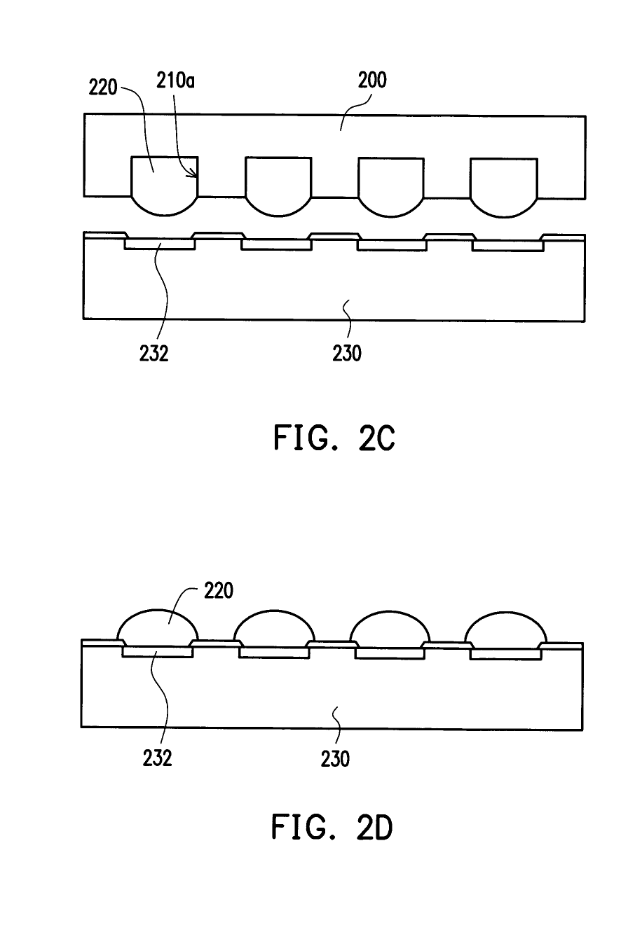

FIGS. 2A-2D show the bump transfer process in accordance with the first embodiment of the present invention. Referring to FIG. 2A, a transfer plate 200 is provided. The transfer plate 200 includes a plurality of fix structures 210a for fixing and accommodating the solder bumps 220 (see FIG. 2B). In the first embodiment, the material of the transfer plate 200 can be silicon, quartz, metal, or ceramics. The transfer plate 200 is used as a support structure for forming solder bumps 220. Further, the fix structures 210a can be concave structures. The concave structures are on the surface of the transfer plate 200.

Referring to FIG. 2A, the transfer plate 200 can be re-used. The transfer plate available in a variety of sizes can be used to form a plurality of solder bumps with a specific size and a specific interval. In addition, the fix structures 210a can be designed deeper or wider or can be different shapes such as sphere or conoid. Hence, the size and the volume of the solder bump formed by using the transfer plate can be effectively controlled to provide a uniform shape.

Referring to FIG. 2B, a plurality of solder bumps are formed in the fix structures 210a of the transfer plate 200 by using dipping. It should be noted that an adhesive layer, such as a solder wetting layer 212 can be formed on the inner surface of the fix structures 210a to increase the surface adhesion between the solder bumps 220 and the fix structures 210a. The material of the solder wetting layer 212 is Cu, Au, Ni, Pt, Pd, Ag or alloys thereof. Because by using the transfer plate of this invention, no photolithography technology is used to form the patterned photoresist layer, the bump transfer process is much simpler and faster. In addition, no wet cleaning process is required. Therefore, the present invention effectively reduces the cost and time for the bump transfer process. Furthermore, the solder bumps are formed by dipping, which can enhance the chip package reliability because the voids inside the solder bumps will be reduced.

Referring to FIG. 2C, a carrier 230 is placed below the transfer plate 200. Then the transfer plate 200 is flipped upside-down to make the solder bumps face toward the carrier 230. In the first embodiment, the carrier 230 is a wafer or a substrate. The carrier 230 has a plurality of bump pads 232 on its surface. The bump pads 232 correspond to the concaves 210a and the solder bumps 220 respectively. Then the solder bumps 220 are melted so that the solder bumps 220 leave the fix structures 210a due to the gravity and are transferred to the bump pads 232 of the carrier 230. Referring to FIG. 2D, after the bump transfer process is finished, the solder bumps 220 are formed on the bump pads 232 of the carrier 230.

Referring to FIG. 2C, the solder bumps 220 can be melted by melting at a high temperature or using laser to heat up the solder bumps 220. Furthermore, the cohesive force of the solder bumps will reduce the adhesive force between the solder bumps 220 and the fix structures 210a after the solder bumps 220 are melted. When the adhesive force is lower than the gravity, the solder bumps 220 leave the fix structures 210a due to the gravity and are transferred to the bump pads 232 of the carrier 230. In addition, to prevent the solder bumps 220 from staying at the transfer plate 200, an additional force such as a force parallel to the gravity can be applied to assist the transfer process. Another way to assist the transfer process is to reduce the distance between the solder bumps 220 and the carrier 230 and to make the solder bumps 220 slightly contact the carrier 230. Then the solder bumps 220 and the carrier 230 are moved away from each other. Due to the adhesive force between the solder bumps 220 and the bump pads, the solder bumps 220 can be more easily transferred to the bump pads.

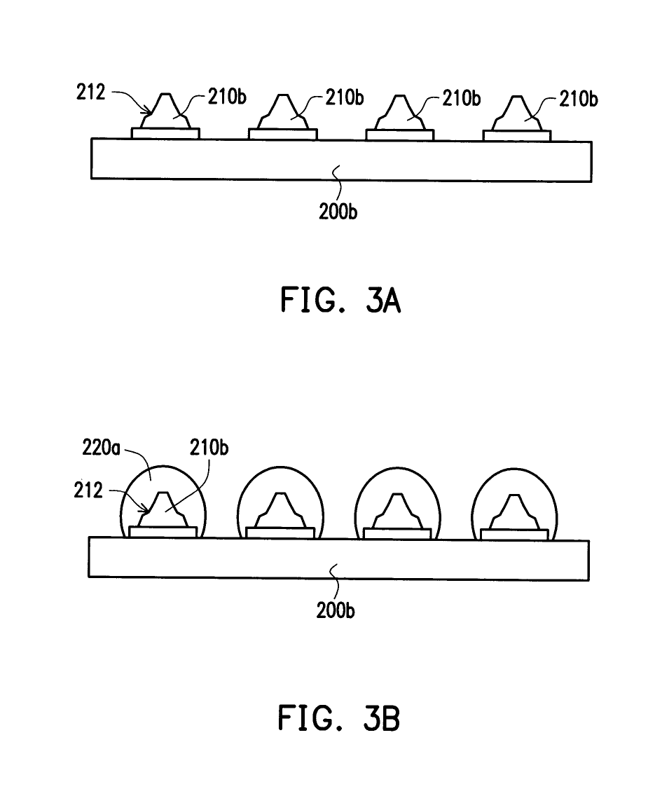

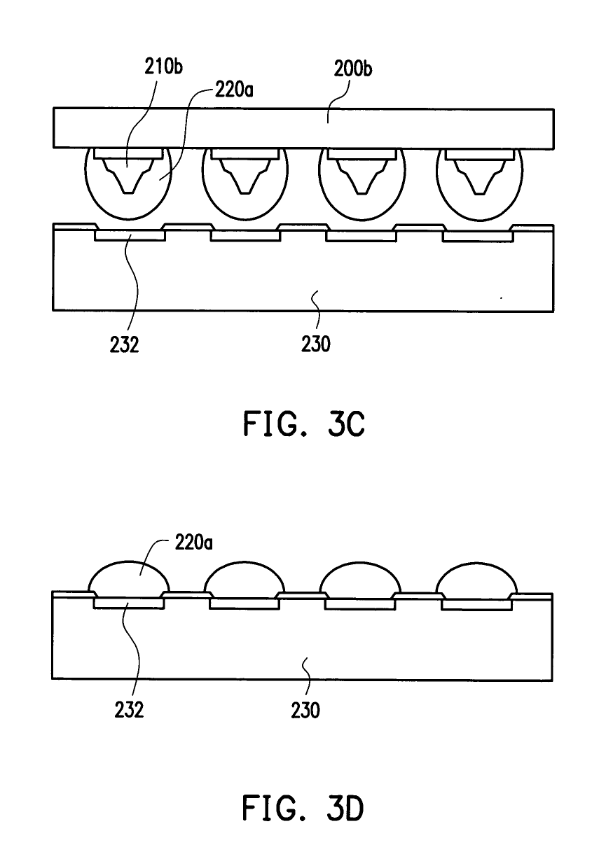

FIGS. 3A-3D show the bump transfer process in accordance with the second embodiment of the present invention. Referring to FIG. 3A, a transfer plate 200b is provided. The transfer plate 200b includes a plurality of fix structures 210b for fixing and accommodating the solder bumps 220a (see FIG. 3B). In the second embodiment, the material of the transfer plate 200b can be silicon, quartz, metal, or ceramics. The transfer plate 200b is used as a support structure for forming solder bumps 220a. Further, the fix structures 210b can be convex structures. The convex structures are on the surface of the transfer plate 200b. The material of the convex structures is the same as the transfer plate 200b. In addition, the fix structures 201b can be designed higher or wider or can be different shapes such as triangular pyramid or conoid. Other shapes such as branch shapes or needle shapes can also be used in the present invention.

Referring to FIG. 3B, a plurality of solder bumps are formed in the fix structures 201b of the transfer plate 200b by using dipping. It should be noted that a solder wetting layer 212 can be formed on the outer surface of the fix structures 210b to increase the surface adhesion between the solder bumps 220a and the fix structures 210b. The material of the solder wetting layer 212 is Cu, Au, Ag, Pt, Pd, Ni or alloys thereof.

Referring to FIG. 3C, a carrier 230 is placed below the transfer plate 200b. Then the transfer plate 200b is flipped upside-down to make the solder bumps face toward the carrier 230. In the second embodiment, the carrier 230 is a wafer or a substrate. The carrier 230 has a plurality of bump pads 232 on its surface. The bump pads 232 correspond to the fix structures 210b and the solder bumps 220a respectively. Then the solder bumps 220a are melted so that the solder bumps 220a leave the convexes 210b due to the gravity and are transferred to the bump pads 232 of the carrier 230. Referring to FIG. 3D, after the bump transfer process is finished, the solder bumps 220a are formed on the bump pads 232 of the carrier 230.

Referring to FIG. 3C, the solder bumps 220a can be melted by melting at a high temperature or using laser to heat up the solder bumps 220a. Furthermore, the cohesive force of the solder bumps will reduce the adhesive force between the solder bumps 220a and the fix structures 210b after the solder bumps 220a are melted. When the adhesive force is lower than the gravity, the solder bumps 220a leave the fix structures 210b due to the gravity and are transferred to the bump pads 232 of the carrier 230. In addition, to prevent the solder bumps 220 from staying at the transfer plate 200, the methods used in the first embodiment also can be applied in the second embodiment.

The present invention provides a bump transfer fixture for accommodating a plurality of solder bumps. The bump transfer fixture at least comprises a transfer plate having a plurality of fix structures. The plurality of fix structures are disposed on the surface of the transfer plate. Each of the plurality of fix structures accommodates one of the bumps. The fix structures can be concave or convex structures. By using the transfer plate to form the solder bumps, no photolithography technology is used to form the patterned photoresist layer. Hence, the bump transfer process is much simpler and faster. In addition, no wet cleaning process is required. Therefore, the present invention effectively reduces the cost and time for the bump transfer process.

Accordingly, the present invention has at least the following advantages:

1. The bump transfer fixture of the present invention can be re-used to reduce the cost of the process.

2. The solder bumps can be easily adhered to the fix structures of the present invention so that the bump transfer process is simplified.

3. The present invention can enhance the chip package reliability because the voids within the solder bumps will be reduced.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

1. A bump transfer fixture for accommodating a plurality of bumps, said bump transfer fixture comprising:
a transfer plate having a plurality of fix structures, said plurality of fix structures being disposed on a surface of said transfer plate, each of said plurality of fix structures accommodating one of the plurality of bumps.

2. The bump transfer fixture of claim 1, wherein each said plurality of fix structures is a concave structure.

3. The bump transfer fixture of claim 1, wherein each said plurality of fix structures is a convex structure.

4. The bump transfer fixture of claim 1, wherein said transfer plate is comprised of metal.

5. The bump transfer fixture of claim 1, wherein said transfer plate is comprised of silicide.

6. The bump transfer fixture of claim 1, wherein said transfer plate is comprised of quartz.

7. The bump transfer fixture of claim 1, wherein said transfer plate is comprised of ceramic.

8. The bump transfer fixture of claim 1, further comprising a plurality of adhesive layers, each of said plurality of adhesive layers being on the surface of one of said plurality of fix structures.

9. A bump transfer fixture for accommodating a plurality of solder bumps, said bump transfer fixture at least comprising:
a transfer plate having a plurality of concave structures, said plurality of concave structures being disposed on a surface of said transfer plate, each of said plurality of concave structures accommodating one of the plurality of solder bumps.

10. The bump transfer fixture of claim 9, wherein said transfer plate is comprised of metal.

11. The bump transfer fixture of claim 9, wherein said transfer plate is comprised of silicide.

12. The bump transfer fixture of claim 9, wherein said transfer plate is comprised of quartz.

13. The bump transfer fixture of claim 9, wherein said transfer plate is comprised of ceramic.

14. The bump transfer fixture of claim 9, further comprising a plurality of solder wetting layers, each of said plurality of solder wetting layers being on the surface of one of said plurality of concave structures.

15. A bump transfer fixture for accommodating a plurality of solder bumps, said bump transfer fixture at least comprising:
a transfer plate having a plurality of convex structures, said plurality of convex structures being disposed on a surface of said transfer plate, each of said plurality of convex structures adhering one of the plurality of solder bumps.

16. The bump transfer fixture of claim 15, wherein said transfer plate is comprised of metal.

17. The bump transfer fixture of claim 15, wherein said transfer plate is comprised of silicide.

18. The bump transfer fixture of claim 15, wherein said transfer plate is comprised of quartz.

19. The bump transfer fixture of claim 15, wherein said transfer plate is comprised of ceramic.

20. The bump transfer fixture of claim 15, further comprising a plurality of solder wetting layers, each of said plurality of solder wetting layers being on the surface of one of said plurality of convex structures.
